(19) United States
(12) Patent Application Publication
(10) Pub. No.: US 2026/0362816 A1
(43) Pub. Date: Nov. 12, 2026

(54) MULTI-CHIP MODULE WITH BACK-TO-BACK BONDING AND SEMICONDUCTOR-CONTROLLED RECTIFIER

(71) Applicant: GlobalFoundries Singapore Pte. Ltd., Singapore (SG)

(72) Inventors: Ting Yang, Singapore (SG); Jie Zeng, Singapore (SG); Kyong Jin Hwang, Singapore (SG)

(21) Appl. No.: 19/200,999

(22) Filed: May 7, 2025

(51) Int. Cl. H10D 89/60; H10P 54/00; H10W 80/00

(52) U.S. Cl. CPC H10D 89/713; H10P 54/00; H10W 80/301

(57) ABSTRACT

Disclosed is a chip-stack multi-chip module structure. The structure includes a first chip and a second chip. The first chip includes a first semiconductor substrate and the second chip includes a second semiconductor substrate. Back surfaces of the first and second semiconductor substrates are bonded together. The structure also includes a bidirectional semiconductor-controlled rectifier (SCR). The SCR has a first portion, which includes P-type and N-type doped regions in the first semiconductor substrate, and a second portion, which similarly includes P-type and N-type doped regions in the second semiconductor substrate and which abuts the first portion at the bonded back surfaces. Also disclosed is a method of forming the structure.

### BACKGROUND

The present disclosure relates to multi-chip structures and, more particularly, to embodiments of a multi-chip module including a semiconductor-controlled rectifier for across-module electrostatic discharge (ESD) protection and a method of forming the multi-chip module.

A chip-stack multi-chip module (MCM) can include two or more chips stacked vertically, bonded together, and attached to a chip carrier or package. The chips can further be electrically connected to each other and to the carrier or package to enable chip-to-chip communication. While each individual chip in a chip-stack MCM may include ESD protection device(s), such chip-stack MCMs may suffer from a lack of effective across-module (i.e., chip-to-chip) ESD protection.

### SUMMARY

Disclosed herein are embodiments of a multi-chip module (MCM) structure. Generally, the structure can include a first chip including a first semiconductor substrate with a first back surface and a second chip including a second semiconductor substrate with a second back surface attached to the first back surface. The structure can further include a semiconductor-controlled rectifier (SCR). The SCR can have a first portion in the first semiconductor substrate and a second portion in the second semiconductor substrate immediately adjacent to the first portion.

In some embodiments, the structure can include: a first chip including a first semiconductor substrate with a first back surface and a first front surface opposite the first back surface and a second chip including a second semiconductor substrate with a second back surface attached to the first back surface and a second front surface opposite the second back surface. The structure can further include a bidirectional SCR between the first front surface and the second front surface. The SCR can include: a first P-type well region in the first semiconductor substrate; a first P-type contact region and a first N-type contact region in the first P-type well region at the first front surface; a second P-type well region in the second semiconductor substrate adjacent the second front surface; a second P-type contact region and a second N-type contact region in the second P-type well region at the second front surface; and an N-type well region extending between the first P-type well region and the second P-type well region.

Also disclosed herein are embodiments of a method of forming the structure. The method can include forming a first portion of a semiconductor-controlled rectifier (SCR) in a first semiconductor substrate and a second portion of the SCR in a second semiconductor substrate. The method can further include attaching a first back surface of the first semiconductor substrate to a second back surface of the second semiconductor substrate so that the first portion of the SCR is immediately adjacent to the second portion.

It should be noted that all aspects, examples, and features of disclosed embodiments mentioned in the summary above can be combined in any technically possible way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIGS. 1A-1E are cross-section diagrams illustrating disclosed embodiments of a structure;

FIG. 2 is a schematic diagram illustrating a bidirectional semiconductor-controlled rectifier (SCR) in the structure of FIGS. 1A-1E;

FIG. 3 is a flow diagram illustrating disclosed embodiments of a method of forming the structure; and

FIG. 4.1-9 are cross-section diagrams illustrating partially completed semiconductor structures formed according to the disclosed embodiments of the method.

### DETAILED DESCRIPTION

As mentioned above, a chip-stack multi-chip module (MCM) can include two or more chips stacked vertically, bonded together, and attached to a chip carrier or package. The chips can further be electrically connected to each other and to the carrier or package to enable chip-to-chip communication. While each individual chip in a chip-stack MCM may include ESD protection device(s), such chip-stack MCMs may suffer from a lack of effective across-module (i.e., chip-to-chip) ESD protection.

In view of the foregoing, disclosed herein are embodiments of a chip-stack multi-chip module (MCM) structure (hereinafter referred to as the structure). The structure can include a first chip and a second chip. The first chip can include a first semiconductor substrate and the second chip can include a second semiconductor substrate. Back surfaces of the first and second semiconductor substrates can be bonded. The structure can further include a semiconductor-controlled rectifier (SCR) (e.g., a silicon-controlled rectifier) and, particularly, a bidirectional semiconductor-controlled rectifier. The SCR can have a first portion, which includes P-type and N-type doped regions in the first semiconductor substrate, and a second portion, which similarly includes P-type and N-type doped regions in the second semiconductor substrate and which abuts the first portion at the bonded back surfaces. Also disclosed herein are embodiments of a method of forming the structure.

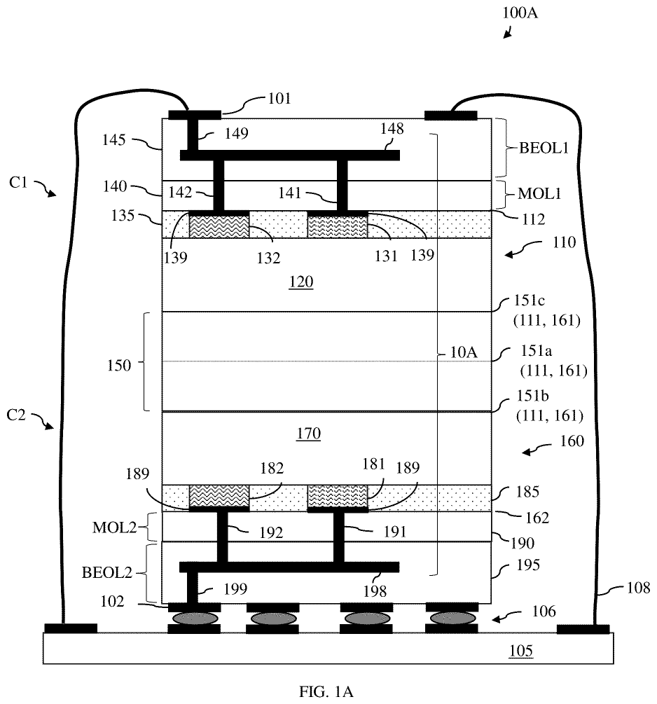

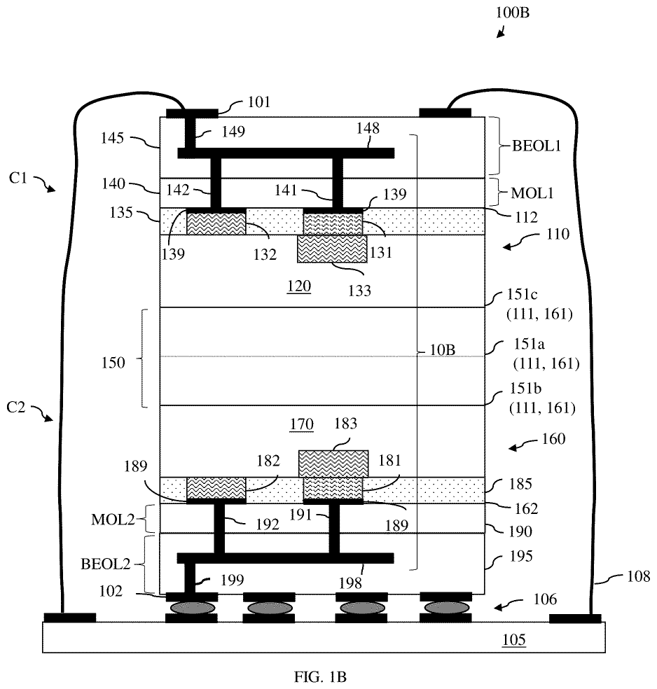

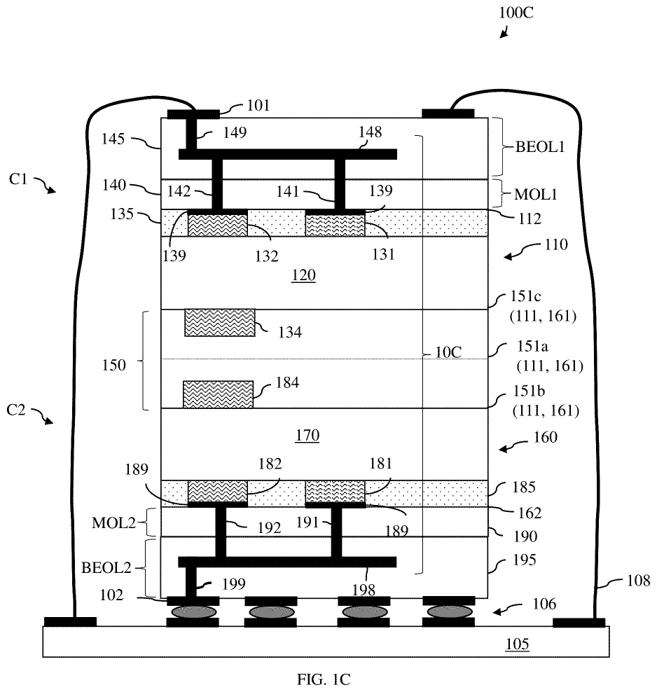

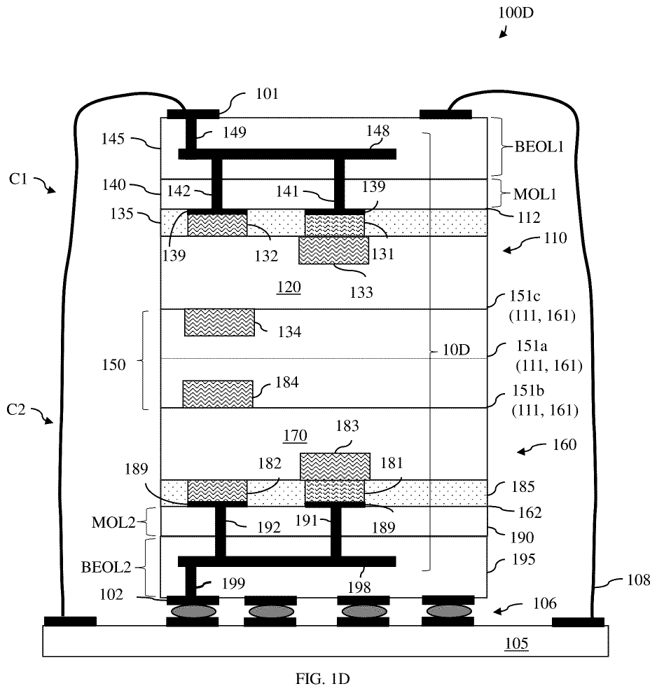

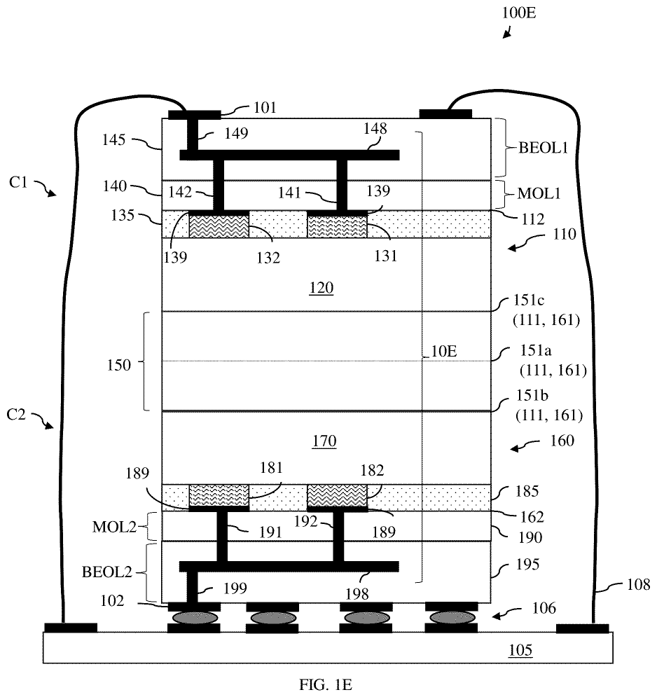

More particularly, FIGS. 1A-1E are cross-section diagrams illustrative of various embodiments of the disclosed structure 100A-100E, respectively. As illustrated in FIGS. 1A-1E, structure 100A, 100B, 100C, 100D, 100E can include a first chip (C1) and a second chip (C2).

C1 can include a first semiconductor substrate 110. First semiconductor substrate 110 can be a silicon substrate, a silicon germanium substrate, or a substrate of any other suitable semiconductor material. First semiconductor substrate 110 can be monocrystalline in structure and can have a first back surface 111 and a first front surface 112 opposite the first back surface 111.

C2 can include a second semiconductor substrate 160. Second semiconductor substrate 160 can be a silicon substrate, a silicon germanium substrate, or a substrate of any other suitable semiconductor material. In some embodiments, first semiconductor substrate 110 and second semiconductor substrate 160 can be made of the same or similar semiconductor material(s). In other embodiments, first semiconductor substrate 110 and second semiconductor substrate 160 can be made of different semiconductor materials. Second semiconductor substrate 160 can be monocrystalline in structure and can have a second back surface 161 and second front surface 162 opposite the second back surface 161.

C1 can be attached to C2 and, more specifically, first back surface 111 of first semiconductor substrate 110 can be attached to second back surface 161 of second semiconductor substrate 160. Attachment of first back surface 111 to second back surface 161 can be through semiconductor surface-to-semiconductor surface bonding, such as through direct bonding (also referred to herein as fusion bonding) or anodic bonding such that first and second back surfaces 111 and 161 are also referred to as bonded back surfaces 111 and 161.

Structure 100A-100E can further include a semiconductor-controlled rectifier (SCR) 10A-10E (e.g., a silicon-controlled rectifier). SCR 10A-10E can be a bidirectional SCR. The SCR 10A-10E can have a portion, which includes P-type and N-type doped regions in first semiconductor substrate 110, and a second portion, which similarly includes P-type and N-type doped regions in the second semiconductor substrate 160 and which abuts the first portion at the bonded back surfaces 111 and 161. As illustrated in FIGS. 1A-1E, the location of the bonded back surfaces 111 and 161 (as indicated by reference numbers 151a, 151b and 151c) can vary relative one of the doped regions within SCR 10A-10E and, particularly, relative to an N-type well region (NWELL) 150 within SCR 10A-10E, as discussed in greater detail below.

For purposes of this disclosure a well region refers to a doped region within a semiconductor body (e.g., a semiconductor substrate or semiconductor layer). A well region can be buried within the semiconductor body (e.g., separated from back and front surfaces). Alternatively, a well region could extend from one surface of the semiconductor body some predetermined distance (e.g., partially into the semiconductor body or completely through the semiconductor body to the opposite surface). A well region can be doped so as to have P-type conductivity (i.e., so as to be a P-type well region (PWELL)). Alternatively, a well region can be doped so as to have N-type conductivity (i.e., so as to be an NWELL). For purposes of this disclosure, a contact region refers to another doped region within a semiconductor body (e.g., a semiconductor substrate or semiconductor layer). A contact region can be doped so as to have P-type conductivity (i.e., so as to be a P-type contact region). Alternatively, a contact region can be doped so as to have N-type conductivity (i.e., so as to be an N-type contact region). Typically, contact regions have relatively high conductivity. For example, a P-type contact region will have higher P-type conductivity than any PWELLs and an N-type contact region will have higher N-type conductivity than any NWELLs. A contact region can be located within the semiconductor body at one surface of the semiconductor body. A contact region can be within or immediately adjacent to a well region and will typically be relatively shallow in depth as compared to the well region. Types of dopants that can be used to achieve P-type conductivity or N-type conductivity vary depending upon the type of semiconductor material and are discussed in greater detail below.

Generally, SCR 10A-10E can include, between first front surface 112 and the second front surface 162: a first PWELL 120 in first semiconductor substrate 110; a first P-type contact region 132 and a first N-type contact region 131 in first PWELL 120 at the first front surface 112; an NWELL 150 immediately adjacent to first PWELL 120; a second PWELL 170 in second semiconductor substrate 160 immediately adjacent NWELL 150; and a second P-type contact region 182 and a second N-type contact region 181 in the second PWELL 170 at the second front surface 162.

As illustrated in SCR 10A-10D, first N-type contact region 131 and first P-type contact region 132 can be essentially vertically aligned with second N-type contact region 181 and the second P-type contact region 182, respectively. That is, first N-type contact region 131 can at least partially overlay (e.g., fully overlay, as illustrated) second N-type contact region 181 and first P-type contact region 132 can at least partially overlay (e.g., fully overlay, as illustrated) second P-type contact region 182. However, alternatively, as illustrated in SCR 10E, first N-type contact region 131 and first P-type contact region 132 can be essentially vertically aligned with second P-type contact region 182 and the second N-type contact region 181, respectively. That is, first N-type contact region 131 can at least partially overlay (e.g., fully overlay, as illustrated) second P-type contact region 182 and first P-type contact region 132 can at least partially overlay (e.g., fully overlay, as illustrated) second N-type contact region 181.

First isolation regions 135 can extend into first semiconductor substrate 110 from first front surface 112 and can laterally surround the first N-type and first P-type contact regions 131-132. Thus, first N-type and first P-type contact regions 131-132 are physically separated from each other. Second isolation regions 185 can extend into second semiconductor substrate 160 from second front surface 162 and can laterally surround the second N-type and first P-type contact regions 181-182. Thus, second N-type and first P-type contact regions 181-182 are physically separated from each other. First isolation regions 135 and second isolation regions 185 can, for example, be shallow trench isolation (STI) regions. Those skilled in the art will recognize that an STI region includes a trench. The trench can be relatively shallow. For example, the bottom of the trench can be at approximately the same depth or somewhat deeper than the bottom of an adjacent contact region but shallow than any well region below. The trench can further be filled with one or more layers of isolation material (e.g., silicon dioxide, silicon oxynitride, silicon nitride, or any other suitable isolation material).

As mentioned above and illustrated in FIGS. 1A-1E, the location of the bonded back surfaces 111 and 161 (as indicated by reference numbers 151a, 151b and 151c) can vary relative to NWELL 150 within SCR 10A-10E between first PWELL 120 and second PWELL 170.

For example, in some embodiments, NWELL 150 can be partially in first semiconductor substrate 110 and also partially in second semiconductor substrate 160. For example, part of NWELL 150 can be with first semiconductor substrate 110 extending from first PWELL 120 to first back surface 111 and part of NWELL 150 can be in second semiconductor substrate 160 extending between second back surface 161 and second PWELL 170. In this case, the bonded back surfaces 111 and 161 are within NWELL 150 (at location 151a).

In other embodiments, NWELL 150 can be formed within first semiconductor substrate 110 only. For example, NWELL 150 can be with first semiconductor substrate 110 extending from first PWELL 120 to first back surface 111 and second PWELL 170 can be within second semiconductor substrate 160 extending from second back surface 161 to second front surface 162. In this case, the bonded back surfaces 111 and 161 are below NWELL 150 (at location 151b).

In still other embodiments, NWELL 150 can be formed within second semiconductor substrate 160 only. For example, NWELL 150 can be with second semiconductor substrate 160 extending from second back surface 161 to second PWELL 170 and first PWELL 120 can be within first semiconductor substrate 110 extending from first front surface 112 to first back surface 111. In this case, the bonded back surfaces 111 and 161 are above NWELL 150 (at location 151c).

In some embodiments, the SCR can further include additional PWELLs. For example, referring to structure 100B of FIG. 1B, SCR 10B can also include an additional PWELL 133 in first PWELL 120 between first N-type contact region 131 and first back surface 111. Optionally, additional PWELL 133 can be separated from NWELL 150 by some distance, as illustrated. SCR 10B can also include an additional PWELL 183 in second PWELL 170 between the second N-type contact region 181 and second back surface 161. Optionally, additional PWELL 183 can be separated from NWELL 150 by some distance, as illustrated. Additional PWELLs 133, 183 can have a higher P-type conductivity level than first PWELL 120 and second PWELL 170 and, optionally, a lower P-type conductivity than first P-type contact region 132 and second P-type contact region 182.

Referring to structure 100C of FIG. 1C, SCR 10C can also include additional PWELLs 134 and 184 in NWELL 150 adjacent opposite junctions with first PWELL 120 and with second PWELL 170. As illustrated, additional PWELL 134 can be aligned vertically with (i.e., can at least partially underlay) first P-type contact region 132 and additional PWELL 184 can be aligned vertically with (i.e., can at least partially overlay) second P-type contact region 182. Additional PWELLs 134, 184 can have a higher P-type conductivity level than first PWELL 120 and second PWELL 170 and, optionally, a lower P-type conductivity than first P-type contact region 132 and second P-type contact region 182.

Referring to structure 100D of FIG. 1D, SCR 10D can include all of the additional PWELLs 133, 134, 183, and 184, as described in detail above and illustrated in FIGS. 1B and 1C.

Referring again to structures 100A-100E of FIGS. 1A-1E, optionally, top surfaces of first N-type and P-type contact regions 131-132 distal to first PWELL 120 can be covered with first metal silicide layers 139. Also optionally, top surfaces of second N-type and P-type contact regions 181-182 can covered with second metal silicide layers 189. Examples of metal silicide materials that could be used for first metal silicide layers 139 and/or second metal silicide layers 189 include cobalt silicide (CoSi), nickel silicide (NiSi), tungsten silicide (WSi), titanium silicide (TiSi), or any other suitable metal silicide material.

C1 can further include a stack of first dielectric layers (including first middle of the line (MOL) dielectric layers 140 and first back end of the line (BEOL) dielectric layers 145) adjacent to first front surface 112. C1 can further include a first pad 101 (e.g., an input/output pad, a power pad, etc.) adjacent to an outermost first dielectric layer distal to first front surface 112. C1 can further include first interconnects (including first MOL contacts 141 and 142 and a first BEOL wires 148 and vias 149), which are within first dielectric layers 140, 145 and configured to electrically connect first P-type contact region 132 and first N-type contact region 131 to first pad 101. C2 can further include a stack of second dielectric layers (including second MOL dielectric layers 190 and second BEOL dielectric layers 195) adjacent to second front surface 162. C2 can further include a second pad 102 (e.g., an input/output pad, a power pad, etc.) adjacent to an outermost second dielectric layer distal to second front surface 162. C2 can further include second interconnects (including second MOL contacts 191 and 192 and second BEOL wires 198 and vias 199), which are within second dielectric layers 190, 195 and configured to electrically connect second P-type contact region 182 and second N-type contact region 181 to second pad 102. MOL and BEOL materials (e.g., dielectric layers, interconnects, pads, etc.) are well known in the art and, thus, details thereof have been omitted from the specification in order to allow the reader to focus on the salient aspects of the disclosed embodiments (e.g., related to the SCR configuration).

Structure 100A-100E can further include a chip carrier 105 (or other form of chip package). The chip stack (including C1 bonded back-to-back to C2) can be attached to a chip carrier 105 (or package) through connectors 106, which facilitate communication between the chip carrier 105 (or package) and C2. For example, pads (e.g., including second pad 102) on the outermost surface of second dielectric layers of C2 can be electrically connected to pads on chip carrier 105 (e.g., using solder or copper micro-bumps). Additionally, pads (e.g., including first pad 101) on the outermost surface of first dielectric layers of C1 can be electrically connected to pads on chip carrier 105 (e.g., see wires 108), which facilitate communication between chip carrier 105 and C1. Although not shown, chip carrier 105 can include wire interconnects between pads thereon and chip stack (including C1 and C2) can include through-substrate vias (TSVs) to further facilitate communication between the chip carrier and the chip stack and further between the two chips. Alternatively, any other now known or subsequently developed techniques for packaging a chip stack MCM and for enabling communication between the chips therein could be employed.

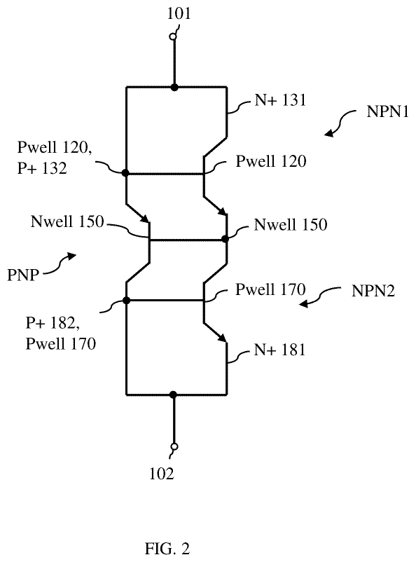

FIG. 2 is a circuit diagram illustrating the bidirectional SCR 10A-10E in structure 100A-100E of FIGS. 1A-1E. As illustrated, SCR 10A-10E includes series-connected NPN-type bipolar junction transistors (BJTs) between first and second pads 101 and 102 and a PNP-type BJT in parallel with the NPN-type BJTs between first and second pads 101 and 102. Specifically, referring to FIG. 2 in combination with any of FIGS. 1A-1E, SCR 10-10E includes a first NPN-type BJT (NPN1), a second NPN-type BJT (NPN2), and a PNP-type BJT (PNP). NPN1 includes: first emitter/collector regions (i.e., first N-type contact region 131 and NWELL 150) and a first base region (i.e., first PWELL 120) between first emitter/collector regions. NPN2 includes: second emitter/collector regions (i.e., NWELL 150 and second N-type contact region 181) and a second base region (i.e., second PWELL 170) between the second emitter/collector regions. PNP includes: third emitter/collector regions (i.e., first P-type contact region 132 in first PWELL 120 and second P-type contact region 182 in second PWELL 170) and a third base region (i.e., NWELL 150) between third emitter/collector regions.

Thus, SCR 10A-10E includes two SCR conduction paths oriented in opposite directions (i.e., SCR 10A-10E is bidirectional). For current flow in a first direction and, particularly, from first pad 101 (i.e., a first terminal) through first P-type contact region 132 to second N-type contact region 181 and thereby to second pad 102 (i.e., a second terminal), NPN2 and PNP form a first SCR conduction path. For current flow in a second direction and, particularly, from second pad 102 through second P-type contact region 182 to first N-type contact region 131 and thereby first pad 101, NPN1 and PNP form a second SCR current path. More particularly, if a high positive voltage pulse is applied across the two pads, NPN2 and PNP will turn on and the first SCR conduction path in the SCR is triggered into a snap-back mode. If a high negative voltage pulse is applied across the two pads, then the NPN1 and PNP will turn on and the second SCR conduction path (which is in the opposite direction of the first SCR conduction path) of the SCR is triggered into a snap-back mode. Configured as described above, the first and second SCR conduction paths can exhibit essentially electrically symmetrical behavior. Thus, the SCR 10A-10E is configured to provide ESD protection to other devices (not shown) including in the chip stack MCM and electrically connected to first pad 101 and/or second pad 102. In embodiments as illustrated in FIGS. 1B-1D, where SCR 10B-10D includes additional PWELLs 133 and 183 abutting the N-type contact regions 131 and 181 in first and second PWELLs 120 and 170, respectively, and/or additional PWELLs 134 and 184 in NWELL 150 at the junctions with first and second PWELLs 120 and 170, respectively, the additional PWELLs may improve performance by tuning trigger and holding voltages (e.g., reducing the trigger voltage and increasing the holding voltage).

It should be noted that in the structure 100A-100E described above and illustrated in FIGS. 1A-1E, respectively, the thicknesses of the first semiconductor substrate 110 and the second semiconductor substrate 160 and the depths and locations of the various well regions can be selected during design and processing such that the two SCR conduction paths (i.e., first conduction path of NPN2 and PNP, which turns on in response to a high positive voltage pulse across the two pads; and a second conduction path of NPN1 and PNP, which turns on in response to a high negative voltage pulse across the two pads) of SCR 10A-10E are essentially electrically symmetric, as illustrated.

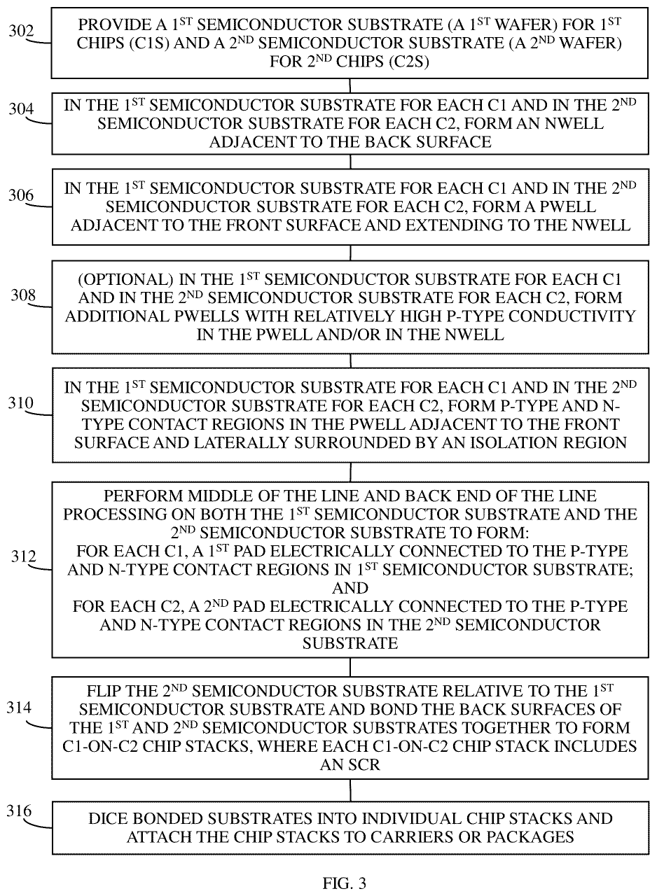

Referring to the flow diagram of FIG. 3, also disclosed herein are method embodiments for forming the above described structure.

The method can include providing a first semiconductor substrate 110 for multiple first chips (C1) and a second semiconductor substrate 160 for multiple second chip (C2) (see process 302). At this stage in the processing these substrates 110, 160 can be monocrystalline semiconductor wafers of, for example, silicon, silicon germanium, or any other suitable semiconductor material. The first semiconductor substrate 110 can have a first back surface 111 and a first front surface 112 opposite the first back surface 111. The second semiconductor substrate 160 can similarly have a second back surface 161 and a second front surface 162 opposite the second back surface 161.

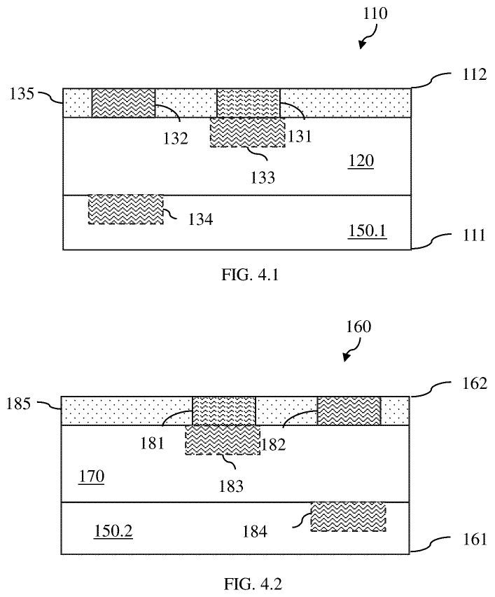

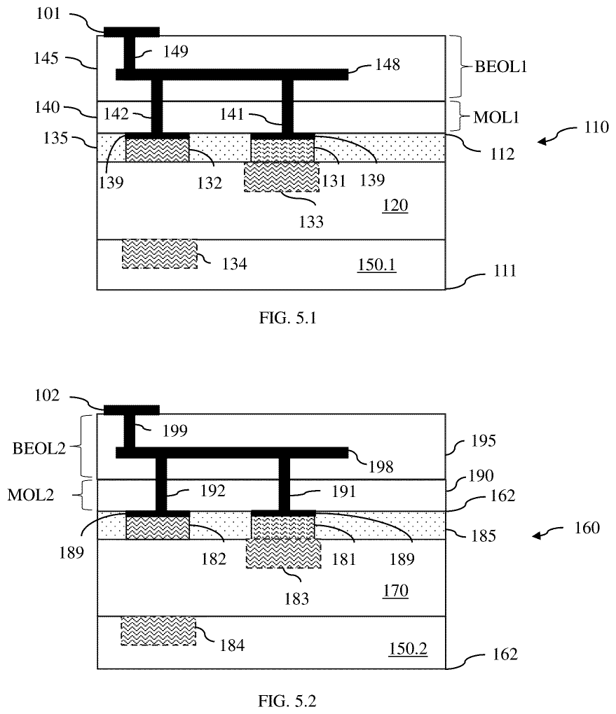

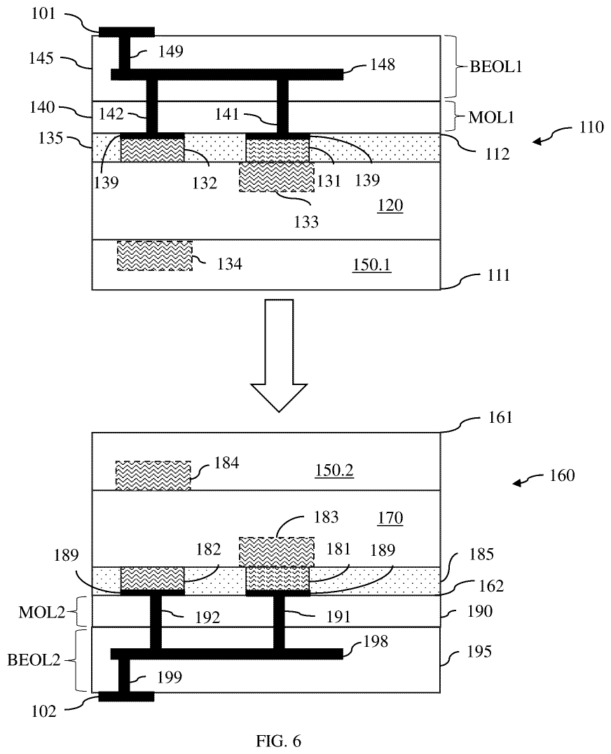

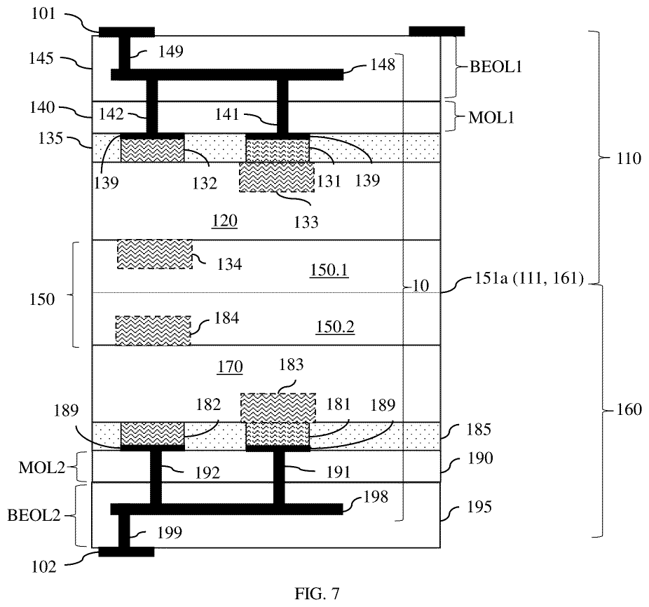

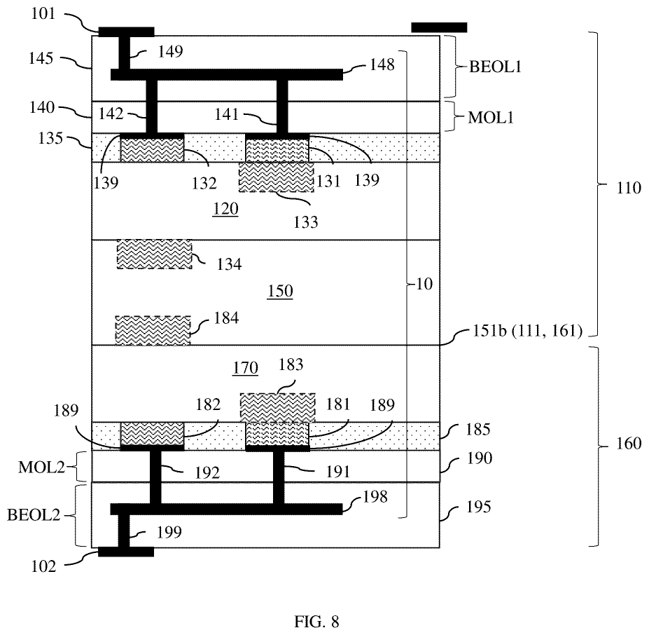

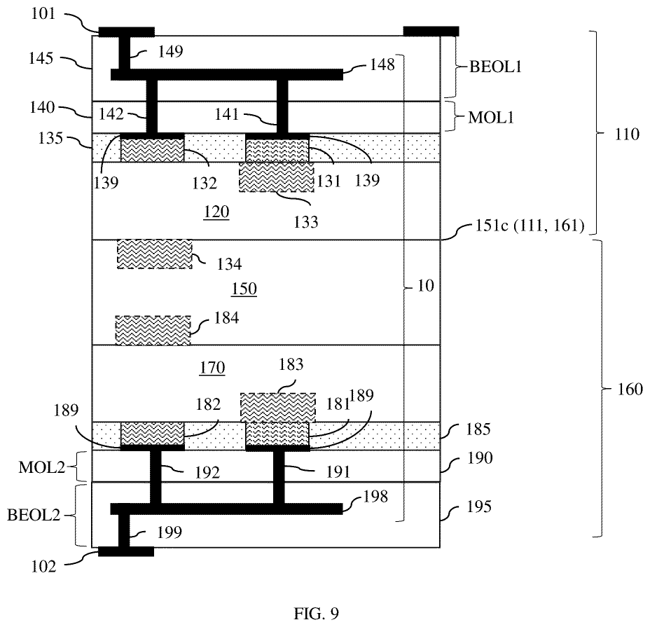

The method can include, for each C1, forming a first portion of a semiconductor-controlled rectifier (SCR) (e.g., a silicon-controlled rectifier) in the first semiconductor substrate 110 and, for each C2, forming a second portion of the SCR in the second semiconductor substrate 160. Specifically, the method can include performing a first series of masked dopant implantation processes directed to the first semiconductor substrate 110 to form the first portion of the SCR and a second series of masked dopant implantation processes directed to the second semiconductor substrate 160 to form the second portion of the SCR (see processes 304-310 and FIG. 4.1 and 4.2).

For example, NWELLs 150.1 and 150.2 can be formed (e.g., by dopant implantation) in lower portions of first and second semiconductor substrates 110 and 160 adjacent first and second back surfaces 111 and 161, respectively (see process 304 and FIG. 4.1 and 4.2).

First and second PWELLs 120 and 170 can be formed (e.g., by dopant implantation) in upper portions of first and second semiconductor substrates 110 extending from first and second front surfaces 112 and 162 to NWELLs 150.1 and 150.2, respectively (see process 306 and FIG. 4.1 and 4.2).

First N-type and P-type contact regions 131-132 can be formed in the first PWELL 120 of the first semiconductor substrate 110 at the first front surface 112 and similarly second N-type and P-type contact regions 181-182 can be formed in the second PWELL 170 of the second semiconductor substrate 160 at the second front surface 162 (see process 310 and FIG. 4.1 and 4.2). For example, first and second shallow trench isolation (STI) regions 135 and 185 can be formed in first and second front surfaces 112 and 162 of first and second semiconductor substrates 110 and 160 (e.g., using conventional STI formation techniques). That is, at the front surface of each substrate a trench can be formed (e.g., lithographically patterned and etched) so as to define discrete areas for the two contact regions. Then, one or more layers of isolation material (e.g., silicon dioxide, silicon nitride, or any other suitable isolation material) can be deposited so as to fill the trench. A chemical mechanical polishing (CMP) process can be performed to remove any isolation material from above the front surface. Masked dopant implantation processes can then be performed to form a P-type contact region in one of the defined areas and an N-type contact regions in the other defined areas such that the resulting N-type and P-type contact regions are laterally surrounded and physically separated by a portion of the STI region. It should be noted that the depths of the STI region and contact regions can be essentially the same (i.e., they can extend from the front surface of the substrate down to the same depth within the substrate), as illustrated. Alternatively, the contact regions could be shallower in depth than the STI region.

Optionally, before forming the STI and contact regions at process 310, one or more additional PWELLs could be formed (e.g., by dopant implantation) in the first PWELL 120 and second PWELL 170 and/or in the NWELL 150 (see process 308 and FIG. 4.1 and 4.2). These additional PWELLs can include an additional PWELL 133 in first PWELL 120 so that in the resulting structure it will be stacked between first N-type contact region 131 and NWELL 150.1 and an additional PWELL 183 in second PWELL 170 so that in the resulting structure it will be stacked between the second N-type contact region 181 and NWELL 150.2. Additionally or alternatively, these additional PWELLs can include an additional PWELL 134 within NWELL 150.1 and abutting first PWELL 120 and positioned so that in the resulting structure it will be aligned vertically with first P-type contact region 132 and an additional PWELL 184 within NWELL 150.2 abutting second PWELL 170 and positioned so that in the resulting structure it will be aligned vertically with second P-type contact region 182. It should be noted that the dopant implantation processes for the additional PWELLs at process 308 can be such that they have a higher P-type conductivity level than first PWELL 120 and second PWELL 170 and, optionally, a lower P-type conductivity than first P-type contact region 132 and second P-type contact region 182.

Optionally, following formation of the STI and contact regions at process 310, first and second metal silicide layers 139 and 189 can be formed on the top surfaces of first N-type and P-type contact regions 131-132 and second N-type and P-type contact regions 181-182. Such metal silicide layers can be formed using conventional metal silicide formation techniques. For example, a metal layer can be deposited over the partially completed structure adjacent to the contact regions. A thermal anneal (heat treatment) can be performed to create silicide at the junctions between the surfaces of the contact regions and the metal layer. Following the thermal anneal, any unreacted metal material can be selectively removed. Examples of metal materials that can be used for silicide formation include, but are not limited to, cobalt, nickel, tungsten, and titanium.

It should be understood that, although not shown, the above-described processes 302-310 can be performed concurrently with the formation of additional front end of the line (FEOL) features and devices for each C1 on first semiconductor substrate 110 and for each C2 on the second semiconductor substrate 160.

Subsequently, middle of the line (MOL) and back end of the line (BEOL) processing can be directed to the first and second semiconductor substrate 110 and 160 (see process 312 and FIG. 5.1 and 5.2). MOL and BEOL processing can specifically be performed (e.g., using conventional MOL and BEOL processing techniques) to form, on the first semiconductor substrate 110 for each C1: a stack of first dielectric layers (including first MOL dielectric layers 140 and first BEOL dielectric layers 145) adjacent to the first front surface 112; a first pad 101 adjacent to an outermost first dielectric layer distal to the first front surface 112; and first interconnects (including first MOL contacts 141-142 and first BEOL wires 148 and vias 149) in the first dielectric layers electrically connecting first P-type contact region 132 and first N-type contact region 131 to first pad 101. Similarly, MOL and BEOL processing can specifically be performed (e.g., using conventional MOL and BEOL processing techniques) to form, on the second semiconductor substrate 160 for each C2: a stack of second dielectric layers (including second MOL dielectric layers 190 and second BEOL dielectric layers 195) adjacent to the second front surface 162 of the second semiconductor substrate 160; a second pad 102 adjacent to an outermost second dielectric layer distal to the second front surface 162; and second interconnects (including second MOL contacts 191-192 and second BEOL wires 198 and vias 199) in the second dielectric layers electrically connecting second P-type contact region 182 and second N-type contact region 181 to second pad 102. It should be understood that the above-described process 312 can be performed concurrently with the formation of additional MOL contacts, BEOL interconnects, and pads for each C1 and C2.

Following BEOL processing, the second semiconductor substrate 160 (second wafer) can be flipped relative to the first semiconductor substrate 110 (first wafer) and the first back surface 111 of the first semiconductor substrate 110 can be attached to the second back surface 161 of the second semiconductor substrate 160, thereby stacking and attaching C1s formed on the first semiconductor substrate 110 to C2s formed on the second semiconductor substrate 160. Attaching the first and second back surfaces 111 and 161 can include performing a semiconductor-to-semiconductor bonding process (referred to herein as a back-to-back (B2B) bonding process). This B2B bonding process could be a direct bonding process during which the first and second back surfaces 111 and 161 are placed immediately adjacent to each other and then heat and pressure are applied to bond the surfaces together. Alternatively, this B2B bonding process could be an anodic bonding process during which the first and second back surfaces 111 and 161 are placed immediately adjacent to each other and then an electric field is applied to bond the surfaces together. Alternatively, any other now known or subsequently developed semiconductor-to-semiconductor bonding process can be employed as long as the process does not result in creation of an isolation region between the surfaces.

By bonding the first back surface 111 to the second back surface 161, multiple C1-on-C2 chips stacks will be formed, each with an SCR 10 with a first portion in the first semiconductor substrate 110 abutting (i.e., immediately adjacent to) a second portion in the second semiconductor substrate 160 (see process 314 and FIGS. 6-7). As discussed in greater detail above with regard to FIG. 2, the SCR 10 is bidirectional with two SCR conduction paths including: first conduction path of NPN2 and PNP, which will turn on in response to a high positive voltage pulse across pads 101 and 102; and second conduction path of NPN1 and PNP, which will turn on in response to a high negative voltage pulse across pads 101 and 102.

For purposes of illustration, the method is described above and illustrated in FIG. 4.1-7 with NWELLs 150.1 and 150.2 being formed at process 304 in the first and second semiconductor substrates 110 and 160, respectively. In this case, when the second semiconductor substrate 160 is flipped (i.e., turned over) and the first and second back surfaces 111 and 161 of the first and second semiconductor substrates 110 and 160 are bonded together, the two NWELLs 150.1 and 150.2 are in direct contact, thereby forming one relatively large NWELL 150 with the location 151a of the bonded surfaces 111 and 161 being within the NWELL 150 in SCR 10 (as shown in FIG. 7). Alternatively, an NWELL 150 could be formed only within first semiconductor substrate 110 (not in second semiconductor substrate 160) at process 304 such that, following process 314, the bonded back surfaces 111 and 161 are below NWELL 150 in SCR 10 (at location 151b see FIG. 8). Alternatively, an NWELL 150 could be formed only within second semiconductor substrate 160 (not within first semiconductor substrate 110) at process 304 such that, following process 314, the bonded back surfaces 111 and 161 are above NWELL 150 (at location 151c see FIG. 9). In any case, the thicknesses of the first semiconductor substrate 110 and the second semiconductor substrate 160 and the depths and locations of the various well regions should be selected during design and processing such that the two SCR conduction paths (i.e., first conduction path of NPN2 and PNP, which will turn on in response to a high positive voltage pulse across the two pads; and second conduction path of NPN1 and PNP, which will turn on in response to a high negative voltage pulse across the two pads) of the resulting SCR are essentially electrically symmetric, as illustrated (e.g., see SCR 10A of FIGS. 1A, 10B of FIGS. 1B, 10C of FIGS. 1C, 10D of FIG. 1D, and 10E of FIG. 1E).

Additional processing can include dicing the bonded wafer structure formed at process 314 into individual C1-on-C2 chip stacks and attaching each chip stack to a chip carrier (e.g., as described in detail above and illustrated in FIGS. 1A-1E) or other package (see process 316).

It should be understood that in the method and structures described above, a semiconductor material refers to a material whose conducting properties can be altered by doping with an impurity. Exemplary semiconductor materials include, for example, silicon-based semiconductor materials (e.g., silicon, silicon germanium, silicon germanium carbide, silicon carbide, etc.) and III-V compound semiconductors (i.e., compounds obtained by combining group III elements, such as aluminum (Al), gallium (Ga), or indium (In), with group V elements, such as nitrogen (N), phosphorous (P), arsenic (As) or antimony (Sb)) (e.g., GaN, InP, GaAs, or GaP). A pure semiconductor material and, more particularly, a semiconductor material that is not doped with an impurity for the purposes of increasing conductivity (i.e., an undoped semiconductor material) is referred to in the art as an intrinsic semiconductor. A semiconductor material that is doped with an impurity for the purposes of increasing conductivity (i.e., a doped semiconductor material) is referred to in the art as an extrinsic semiconductor and will be more conductive than an intrinsic semiconductor made of the same base material. That is, extrinsic silicon will be more conductive than intrinsic silicon; extrinsic silicon germanium will be more conductive than intrinsic silicon germanium; and so on. Furthermore, it should be understood that different impurities (i.e., different dopants) can be used to achieve different conductivity types (e.g., P-type conductivity and N-type conductivity) and that the dopants may vary depending upon the different semiconductor materials used. For example, a silicon-based semiconductor material (e.g., silicon, silicon germanium, etc.) is typically doped with a Group III dopant, such as boron (B) or indium (In), to achieve P-type conductivity, whereas a silicon-based semiconductor material is typically doped with a Group V dopant, such as arsenic (As), phosphorous (P) or antimony (Sb), to achieve N-type conductivity. A gallium nitride (GaN)-based semiconductor material is typically doped with magnesium (Mg) to achieve P-type conductivity and with silicon (Si) or oxygen to achieve N-type conductivity. Those skilled in the art will also recognize that different conductivity levels will depend upon the relative concentration levels of the dopant(s) in a given semiconductor region.

It should be understood that the terminology used herein is for the purpose of describing the disclosed structures and methods and is not intended to be limiting. For example, as used herein, the singular forms “a,” “an,” and “the” are intended to include the plural forms as well, unless the context clearly indicates otherwise. Additionally, as used herein, the terms “comprises,” “comprising,” “includes,” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a first chip including a first semiconductor substrate with a first back surface;
a second chip including a second semiconductor substrate with a second back surface attached to the first back surface; and
a semiconductor-controlled rectifier including a first portion in the first semiconductor substrate and a second portion in the second semiconductor substrate immediately adjacent to the first portion.

2. The structure of claim 1,
wherein the first semiconductor substrate further includes a first front surface opposite the first back surface and the second semiconductor substrate further includes a second front surface opposite the first front surface, and
wherein the semiconductor-controlled rectifier includes, between the first front surface and the second front surface:
a first P-type well region in the first semiconductor substrate;
a first P-type contact region in the first P-type well region at the first front surface;
an N-type well region adjacent the first P-type well region;
a second P-type well region in the second semiconductor substrate adjacent the N-type well region; and
a second N-type contact region in the second P-type well region at the second front surface.

3. The structure of claim 2, wherein the semiconductor-controlled rectifier is a bidirectional semiconductor-controlled rectifier and further includes:
a first N-type contact region in the first P-type well region at the first front surface and electrically connected to the first P-type contact region; and
a second P-type contact region in the second P-type well region at the second front surface and electrically connected to the second N-type contact region.

4. The structure of claim 3, wherein either:
the first N-type contact region and the first P-type contact region are vertically aligned with the second N-type contact region and the second P-type contact region, respectively, or
the first N-type contact region and the first P-type contact region are vertically aligned with the second P-type contact region and the second N-type contact region, respectively.

5. The structure of claim 3,
wherein the first chip further includes:
a stack of first dielectric layers adjacent to the first front surface;
a first pad adjacent to an outermost first dielectric layer distal to the first front surface; and
first interconnects in the first dielectric layers electrically connecting the first P-type contact region and the first N-type contact region to the first pad, and
wherein the second chip further includes:
a stack of second dielectric layers adjacent to the second front surface;
a second pad adjacent to an outermost second dielectric layer distal to the second front surface; and
second interconnects in the second dielectric layers electrically connecting the second P-type contact region and the second N-type contact region to the second pad.

6. The structure of claim 3,
wherein the semiconductor-controlled rectifier further includes: additional P-type well regions in the first P-type well region between the first N-type contact region and the first back surface and in the second P-type well region between the second N-type contact region and the second back surface, and
wherein the additional P-type well regions have a higher P-type conductivity level than the first P-type well region and the second P-type well region.

7. The structure of claim 3,
wherein the semiconductor-controlled rectifier further includes: additional P-type well regions in the N-type well region at opposite junctions with the first P-type well region and with the second P-type well region and aligned vertically with the first P-type contact region and the second P-type contact region, and
wherein the additional P-type well regions have a higher P-type conductivity level than the first P-type well region and the second P-type well region.

8. The structure of claim 3,
wherein the semiconductor-controlled rectifier further includes additional P-type well regions in the following:
the first P-type well region between the first N-type contact region and the first back surface,
the second P-type well region between the second N-type contact region and the second back surface, and
the N-type well region at opposite junctions with the first P-type well region and the second P-type well region and further aligned vertically with the first P-type contact region and the second P-type contact region, and
wherein the additional P-type well regions have a higher P-type conductivity level than the first P-type well region and the second P-type well region.

9. The structure of claim 2, wherein the N-type well region is partially in the first semiconductor substrate extending from the first P-type well region to the first back surface and partially in the second semiconductor substrate extending between the second back surface and the second P-type well region.

10. The structure of claim 2, wherein the N-type well region is within the first semiconductor substrate extending from the first P-type well region to the first back surface and the second P-type well region extends from the second back surface to the second front surface.

11. The structure of claim 2, wherein the first P-type well region extends from the first front surface to the first back surface and the N-type well region is within the second semiconductor substrate extending from the second back surface to the second P-type well region.

12. A structure comprising:
a first chip including a first semiconductor substrate with a first back surface and a first front surface opposite the first back surface;
a second chip including a second semiconductor substrate with a second back surface attached to the first back surface and a second front surface opposite the second back surface;
and a bidirectional semiconductor-controlled rectifier including, between the first front surface and the second front surface:
a first P-type well region in the first semiconductor substrate;
a first P-type contact region and a first N-type contact region in the first P-type well region at the first front surface;
a second P-type well region in the second semiconductor substrate adjacent the second front surface;
a second P-type contact region and a second N-type contact region in the second P-type well region at the second front surface; and
an N-type well region extending between the first P-type well region and the second P-type well region.

13. A method comprising:
forming a first portion of a semiconductor-controlled rectifier in a first semiconductor substrate and a second portion of the semiconductor-controlled rectifier in a second semiconductor substrate; and
attaching a first back surface of the first semiconductor substrate to a second back surface of the second semiconductor substrate so that the first portion is immediately adjacent to the second portion.

14. The method of claim 13, wherein the forming of the first portion of the semiconductor-controlled rectifier in the first semiconductor substrate and the second portion of the semiconductor-controlled rectifier in the second semiconductor substrate includes one of:
forming N-type well regions in the first semiconductor substrate adjacent to the first back surface and in the second semiconductor substrate adjacent to the second back surface;
forming an N-type well region in the first semiconductor substrate only adjacent to the first back surface; and
forming an N-type well region in the second semiconductor substrate only adjacent to the second back surface.

15. The method of claim 13, wherein the forming of the first portion of the semiconductor-controlled rectifier in the first semiconductor substrate and the second portion of the semiconductor-controlled rectifier in the second semiconductor substrate includes:
forming a first P-type well region in the first semiconductor substrate adjacent a first front surface of the first semiconductor substrate;
forming a first P-type contact region and a first N-type contact region in the first P-type well region at the first front surface;
forming a second P-type well region in the second semiconductor substrate adjacent a second front surface of the second semiconductor substrate; and
forming a second P-type contact region and a second N-type contact region in the second P-type well region at the second front surface.

16. The method of claim 15, further comprising performing processing to form:
a stack of first dielectric layers adjacent to the first front surface of the first semiconductor substrate;
a first pad adjacent to an outermost first dielectric layer distal to the first front surface;
first interconnects in the first dielectric layers electrically connecting the first P-type contact region and the first N-type contact region to the first pad;
a stack of second dielectric layers adjacent to the second front surface of the second semiconductor substrate;
a second pad adjacent to an outermost second dielectric layer distal to the second front surface; and
second interconnects in the second dielectric layers electrically connecting the second P-type contact region and the second N-type contact region to the second pad.

17. The method of claim 15,
wherein the forming of the first portion of the semiconductor-controlled rectifier in the first semiconductor substrate and the second portion of the semiconductor-controlled rectifier in the second semiconductor substrate further includes forming additional P-type well regions in at least the first P-type well region and the second P-type well region, and
wherein the additional P-type well regions have a higher P-type conductivity level than the first P-type well region and the second P-type well region.

18. The method of claim 15, wherein the attaching includes performing semiconductor-to-semiconductor bonding process.

19. The method of claim 18, wherein the semiconductor-to-semiconductor bonding process includes any of direct bonding and anodic bonding.

20. The method of claim 15, further comprising: dicing the attached first and second semiconductor substrates to form a chip stack including the semiconductor-controlled rectifier;
and attaching the chip stack to a chip carrier or package.
